(19) United States
(12) Patent Application Publication
(10) Pub. No.: US 2026/0024491 A1
(43) Pub. Date: Jan. 22, 2026

(54) DISPLAY SUBSTRATE AND DISPLAY DEVICE

(71) Applicants: CHENGDU BOE OPTOELECTRONICS TECHNOLOGY CO., LTD., Chengdu, Sichuan (CN); BOE TECHNOLOGY GROUP CO., LTD., Beijing (CN)

(72) Inventors: Qingqing YAN, Beijing (CN); Zhiliang JIANG, Beijing (CN); Binyan WANG, Beijing (CN); Xiaomin YUAN, Beijing (CN)

(21) Appl. No.: 18/869,240

(22) PCT Filed: Jan. 2, 2024
(86) PCT No.: PCT/CN2024/070024

§ 371 Date: Nov. 25, 2024

(30) Foreign Application Priority Data
Jan. 3, 2023 (CN) 202310004907.4

(51) Int. Cl. G09G 3/3233; H10D 86/40; H10D 86/60

(52) U.S. Cl. CPC G09G 3/3233; H10D 86/441; H10D 86/60; G09G 2300/0426; G09G 2300/0452; G09G 2300/0819; G09G 2300/0842; G09G 2300/0861; G09G 2320/0233; G09G 2320/0242

(57) ABSTRACT

A display substrate and a display device are provided. The display substrate includes: a substrate and sub-pixels including a sub-pixel driving circuit and a light-emitting element, the display substrate including a first display area and a second display area located around the first display area, the first display area is provided with the sub-pixel driving circuit and the light-emitting element, the second display area is provided with the light-emitting element, the second display area is not provided with the sub-pixel driving circuit, the anode of the light-emitting element in the second display area is connected to the sub-pixel driving circuit arranged in the first display area through a first conductive trace; the area of at least part of the anode of the second display area is smaller than the area of the anode of the sub-pixel of the same color in the first display area.

### CROSS-REFERENCE TO RELATED APPLICATIONS

The present disclosure is the U.S. national phase of PCT Application PCT/CN2024/070024 filed on Jan. 2, 2024, which claims priority to Chinese patent application No. 202310004907.4 filed on Jan. 3, 2023, the entire contents of which are incorporated herein by reference for all purposes.

### TECHNICAL FIELD

The present disclosure relates to the field of display technology, and in particular to a display substrate and a display device.

### BACKGROUND

In recent years, with the rapid development of the display industry, rigid LCD screens have gradually been unable to meet people's needs. Therefore, organic light-emitting diode displays, known for their flexibility, have emerged. Organic light-emitting diode displays not only have good flexibility, but also have the advantages of thinness, low power consumption, fast response speed, wide viewing angle, etc., and are widely used in various fields.

### SUMMARY

The present disclosure is to provide a display substrate and a display device.

In order to achieve the above objectives, the present disclosure provides the following technical solutions:
the present disclosure provides a display substrate, including: a substrate and a plurality of sub-pixels arranged on the substrate, the sub-pixels including a sub-pixel driving circuit and a light-emitting element, the display substrate including a first display area and a second display area located around the first display area, the first display area being provided with the sub-pixel driving circuit and the light-emitting element, the second display area being provided with the light-emitting element, the second display area being not provided with the sub-pixel driving circuit, the anode of the light-emitting element in the second display area being connected to the sub-pixel driving circuit arranged in the first display area through a first conductive trace, and the anode of the light-emitting element in the first display area being connected to the sub-pixel driving circuit arranged in the first display area through a second conductive trace;

The area of at least part of the anode of the second display area is smaller than the area of the anode of the sub-pixel of the same color in the first display area.

Optionally, the first display area includes a third display area and a transitional display area, and the transitional display area is located between the third display area and the second display area;

The area of at least part of the anode in the transitional display area is smaller than that of the anode of the same color sub-pixel in the third display area, and the area of at least part of the anode in the transitional display area is larger than that of the anode of the same color sub-pixel in the second display area.

Optionally, the sub-pixels include a green sub-pixel, a red sub-pixel and a blue sub-pixel.

The area of the first anode of the transitional display area is smaller than the area of the first anode of the sub-pixel of the same color in the third display area; the area of the first anode of the transitional display area is larger than the area of the first anode of the sub-pixel of the same color in the second display area;
where the first anode is the anode of the green sub-pixel, the red sub-pixel and the blue sub-pixel; or

The first anode is the anode of the green sub-pixel.

Optionally, in the transitional display area and the second display area, the area of the first anode of the sub-pixel of the same color gradually decreases in a direction away from the third display area.

Optionally, in the transitional display area and the second display area, a plurality of pixel repetition units are arranged in sequence along a direction away from the third display area, the pixel repetition unit includes at least one sub-pixel, and in each of the pixel repetition units, the areas of the first anodes of sub-pixels of the same color are equal; the areas of the first anodes of sub-pixels of the same color in different pixel repetition units gradually decrease.

Optionally, the sub-pixels include a green sub-pixel, a red sub-pixel and a blue sub-pixel.

The area of the first anode of the first display area is larger than the area of the first anode of the sub-pixel of the same color in the second display area;
where the first anode is the anode of the green sub-pixel, the red sub-pixel and the blue sub-pixel; or

The first anode is the anode of the green sub-pixel.

Optionally, in the second display area, the area of the first anode of the sub-pixel of the same color gradually decreases in a direction away from the first display area.

Optionally, in the second display area, a plurality of pixel repetition units are arranged in sequence along a direction away from the first display area, the pixel repetition unit includes at least one sub-pixel, and in each of the pixel repetition units, the areas of the first anodes of sub-pixels of the same color are equal; the areas of the first anodes of sub-pixels of the same color in different pixel repetition units gradually decrease.

Optionally, the area of the first anode of the (k+1)-th pixel repeating unit is n times the area of the first anode of the same color sub-pixel of the k-th pixel repeating unit, where k is a positive integer and n is less than 1 and greater than 0.

Optionally, the line width of the second conductive trace is greater than the line width of the first conductive trace.

Optionally, the first conductive trace is transparent, and the second conductive trace is transparent.

Optionally, the area of the orthographic projection of the first conductive trace connected to the light-emitting element of the sub-pixel with the first luminous color on the substrate is equal to the area of the orthographic projection of the second conductive trace connected to the light-emitting element of the sub-pixel with the same luminous color on the substrate.

Optionally, the difference between the sum of the areas of the orthographic projections of the anode of the sub-pixel having the first luminous color and the corresponding first conductive trace on the substrate and the sum of the areas of the orthographic projections of the anode of the sub-pixel having the same luminous color and the corresponding second conductive trace on the substrate is within 10%.

Optionally, the second display area is provided with a gate driving circuit or a light emitting control circuit.

Optionally, the display substrate includes a plurality of power lines, a plurality of light emitting control lines, a plurality of gate lines, a plurality of data lines, a plurality of reset lines, and a plurality of initialization signal lines;

The sub-pixel driving circuit includes: a storage capacitor, a first reset transistor, a data writing transistor, a power control transistor, a light emission control transistor, a second reset transistor, a driving transistor and a compensation transistor;

The compensation transistor includes an active layer and a gate, the active layer of the compensation transistor includes a first electrode, a second electrode, and a channel portion connecting the first electrode and the second electrode, the driving transistor includes an active layer and a gate, the active layer of the driving transistor includes a first electrode, a second electrode, and a channel portion connecting the first electrode and the second electrode;
a first electrode of the compensation transistor is coupled to the second electrode of the driving transistor, and the second electrode of the compensation transistor is coupled to the gate of the driving transistor; the driving transistor is used to drive the light-emitting element to emit light, and the first electrode of the driving transistor is connected to the anode;
a gate electrode of the first reset transistor is coupled to the corresponding reset line, the first electrode of the first reset transistor is coupled to the corresponding initialization signal line, and the second electrode of the first reset transistor is coupled to the gate of the driving transistor;
a gate electrode of the data writing transistor is coupled to the corresponding gate line, the first electrode of the data writing transistor is coupled to the corresponding data line, and the second electrode of the data writing transistor is coupled to the first electrode of the driving transistor;
a gate electrode of the power control transistor is coupled to the corresponding light emitting control line, the first electrode of the power control transistor is coupled to the corresponding power line, and the second electrode of the power control transistor is coupled to the first electrode of the driving transistor;
a gate of the light emitting control transistor is coupled to the corresponding light emitting control line, the first electrode of the light emitting control transistor is coupled to the second electrode of the driving transistor, and the second electrode of the light emitting control transistor is coupled to the corresponding light emitting element;
a gate electrode of the second reset transistor is coupled to the corresponding reset line, the first electrode of the second reset transistor is coupled to the corresponding initialization signal line, and the second electrode of the second reset transistor is coupled to the corresponding light emitting element;
a first plate of the storage capacitor is coupled to the gate of the driving transistor, and a second plate of the storage capacitor is coupled to the corresponding power line.

Optionally, the display substrate includes a first metal layer and a second metal layer located on a side of the first metal layer away from the substrate, the first metal layer includes the initialization signal line and a node connection line, the node connection line connects the gate of the driving transistor and the drain of the compensation transistor, the second metal layer includes a shielding pattern, the shielding pattern is connected to the initialization signal line through a via, and the orthographic projection of the initialization signal line on the substrate at least partially overlaps with the orthographic projection of the node connection line on the substrate.

Optionally, the first metal layer also includes a first adapter block and a second adapter block, the second metal layer also includes a third adapter block, the drain of the light-emitting control transistor is connected to the first adapter block, the drain of the second reset transistor is connected to the second adapter block, the first adapter block and the second adapter block are connected through the third adapter block, and the third adapter block is connected to the anode.

Optionally, the second display area is provided with a data fan-out line connected to the data line, and an orthographic projection of the data fan-out line on the substrate does not overlap with an orthographic projection of the anode on the substrate.

Based on the technical solution of the above-mentioned display substrate, a second aspect of the present disclosure provides a display device, including the above-mentioned display substrate.

### BRIEF DESCRIPTION OF THE DRAWINGS

The drawings described herein are used to provide a further understanding of the present disclosure and constitute a part of the present disclosure. The illustrative embodiments of the present disclosure and their descriptions are used to explain the present disclosure and do not constitute an improper limitation on the present disclosure. In the drawings:

FIGS. 1 and 2 are schematic plan views of a display substrate provided by an embodiment of the present disclosure;

FIGS. 3-5 are schematic diagrams of anodes according to embodiments of the present disclosure;

FIG. 6 is a circuit structure diagram of a sub-pixel driving circuit according to an embodiment of the present disclosure;

FIG. 7 is a schematic diagram of the layout of a semiconductor layer according to an embodiment of the present disclosure;

FIG. 8 is a schematic diagram of the layout of the first gate metal layer according to the first embodiment of the present disclosure;

FIG. 9 is a schematic diagram of a stacking layout of a first gate metal layer and a semiconductor layer according to a first embodiment of the present disclosure;

FIG. 10 is a schematic diagram of the layout of the second gate metal layer according to the first embodiment of the present disclosure;

FIG. 11 is a schematic diagram of a stacked layout of a first gate metal layer, a semiconductor layer, and a second gate metal layer according to a first embodiment of the present disclosure;

FIG. 12 is a schematic diagram of the layout of the first source-drain metal layer according to the first embodiment of the present disclosure;

FIG. 13 is a schematic diagram of a stacked layout of a first gate metal layer, a semiconductor layer, a second gate metal layer, and a first source-drain metal layer according to a first embodiment of the present disclosure;

FIG. 14 is a schematic diagram of the layout of the second source-drain metal layer according to the first embodiment of the present disclosure;

FIG. 15 is a schematic diagram of a stacked layout of a first gate metal layer, a semiconductor layer, a second gate metal layer, a first source-drain metal layer, and a second source-drain metal layer according to a first embodiment of the present disclosure;

FIG. 16 is a schematic diagram of the layout of a transparent conductive layer according to an embodiment of the present disclosure;

FIG. 17 is a schematic diagram of the stacking layout of a first gate metal layer, a semiconductor layer, a second gate metal layer, a first source-drain metal layer, a second source-drain metal layer, and a transparent conductive layer according to a first embodiment of the present disclosure;

FIG. 18 is a schematic diagram of the layout of an anode layer according to an embodiment of the present disclosure;

FIG. 19 is a schematic diagram of the stacking layout of a first gate metal layer, a semiconductor layer, a second gate metal layer, a first source-drain metal layer, a second source-drain metal layer, a transparent conductive layer, and an anode layer according to a first embodiment of the present disclosure;

FIG. 20 is a cross-sectional schematic diagram of a display substrate according to a first embodiment of the present disclosure;

FIG. 21 is a schematic diagram of the stacking layout of a pixel definition layer and an anode layer according to an embodiment of the present disclosure;

FIG. 22 is a schematic diagram of the layout of the semiconductor layer in the second embodiment of the present disclosure;

FIG. 23 is a schematic diagram of the layout of the first gate metal layer in the second embodiment of the present disclosure;

FIG. 24 is a schematic diagram of the stacking layout of the first gate metal layer and the semiconductor layer in the second embodiment of the present disclosure;

FIG. 25 is a schematic diagram of the layout of the second gate metal layer in the second embodiment of the present disclosure;

FIG. 26 is a schematic diagram of a stacked layout of a first gate metal layer, a semiconductor layer, and a second gate metal layer according to a second embodiment of the present disclosure;

FIG. 27 is a schematic diagram of the layout of the first source-drain metal layer in the second embodiment of the present disclosure;

FIG. 28 is a schematic diagram of the stacking layout of the first gate metal layer, the semiconductor layer, the second gate metal layer and the first source-drain metal layer according to the second embodiment of the present disclosure;

FIG. 29 is a schematic diagram of the layout of the second source-drain metal layer in the second embodiment of the present disclosure;

FIG. 30 is a schematic diagram of the stacking layout of the first gate metal layer, the semiconductor layer, the second gate metal layer, the first source-drain metal layer, and the second source-drain metal layer according to the second embodiment of the present disclosure;

FIG. 31 is a schematic diagram of the layout of the transparent conductive layer in the second embodiment of the present disclosure;

FIG. 32 is a schematic diagram of the layout of the second anode layer in an embodiment of the present disclosure;

FIG. 33 is a schematic diagram of the stacking layout of the first gate metal layer, the semiconductor layer, the second gate metal layer, the first source-drain metal layer, the second source-drain metal layer, the transparent conductive layer and the anode layer according to the second embodiment of the present disclosure;

FIG. 34 is a cross-sectional schematic diagram of a display substrate according to the second embodiment of the present disclosure; and

FIG. 35 is a schematic diagram of the stacking layout of the second pixel definition layer and the anode layer according to an embodiment of the present disclosure.

### DETAILED DESCRIPTION

In order to further illustrate the display substrate and the display device provided by the embodiments of the present disclosure, a detailed description is given below in conjunction with the accompanying drawings.

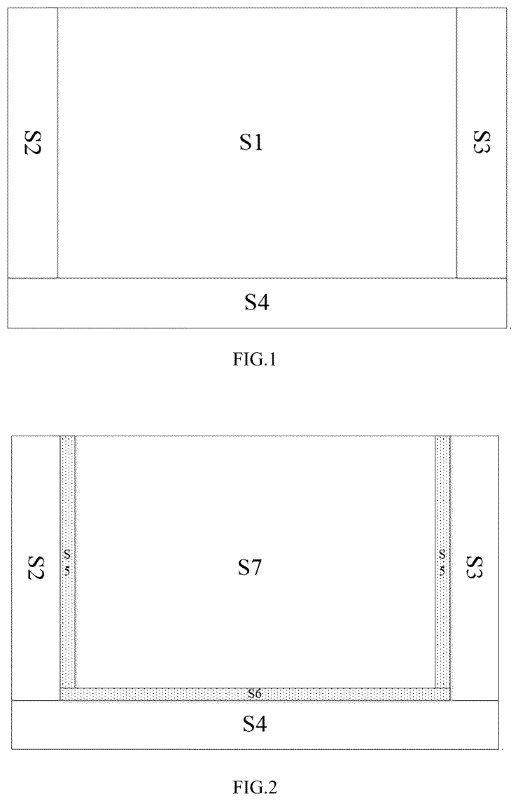

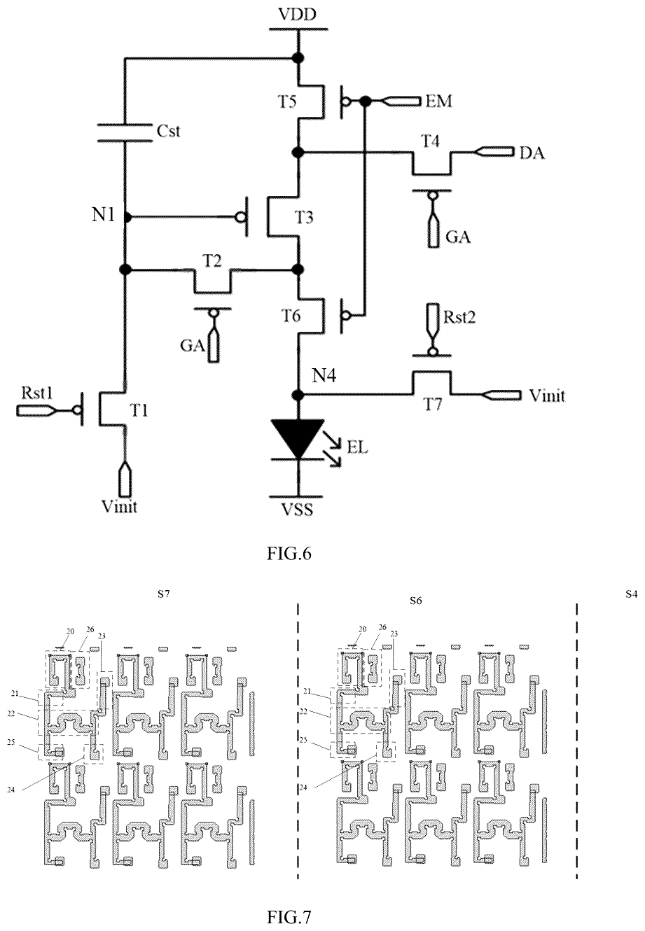

An organic light emitting diode display panel generally includes a substrate and a plurality of sub-pixels arranged on the substrate, and the sub-pixels include a sub-pixel driving circuit and a light-emitting element. The use of GOP technology can effectively reduce the border of the organic light emitting diode display panel. The GOP technology compresses the Fanout into the AA light-emitting area. As shown in FIGS. 1 and 2, the display substrate includes a first display area S1 and a second display area S2/S3/S4 (i.e., the GOP area) located around the first display area S1, where a sub-pixel driving circuit and a light-emitting element are arranged in the first display area S1, and the light-emitting element includes an anode, a cathode, and a light-emitting layer located between the anode and the cathode; a light-emitting element is arranged in the second display area S2/S3/S4, but a sub-pixel driving circuit is not arranged, and the anode of the light-emitting element of the second display area S2/S3/S4 is connected to the sub-pixel arranged in the first display area S1 through a first conductive trace. The driving circuit is connected. Since the first conductive trace needs to extend from the second display area to the first display area, the length of the first conductive trace is relatively long, resulting in a relatively large area of the first conductive trace and the anode of the second display area (as a plate of the N4 point (i.e., the anode point) capacitor of the sub-pixel driving circuit as shown in FIG. 6), which in turn results in a relatively large N4 point capacitor of the sub-pixel driving circuit connected to the light-emitting element of the second display area. The second display area cannot light up or cannot reach the same brightness as the first display area, resulting in an increase in the border of the display substrate at low grayscale, affecting the display effect.

The second display area can be illuminated by sacrificing the demura compensation effect, but the low grayscale yield will be affected. The present disclosure provides a display substrate and a display device, which can improve the display effect of the display substrate.

Based on the existence of the above problems, as shown in FIGS. 1 to 35, the present disclosure provides a display substrate, including: a substrate and a plurality of sub-pixels arranged on the substrate, the sub-pixels including a sub-pixel driving circuit and a light-emitting element. As shown in FIGS. 1 and 2, the display substrate includes a first display area S1 and a second display area S2/S3/S4 located around the first display area, the first display area SI is provided with the sub-pixel driving circuit and the light-emitting element, the second display area S2/S3/S4 is provided with the light-emitting element, and the second display area S2/S3/S4 is not provided with the sub-pixel driving circuit. As shown in FIG. 33, the anode 60 of the light-emitting element in the second display area is connected to the sub-pixel driving circuit arranged in the first display area through a first conductive trace 82; the anode of the light-emitting element in the first display area is connected to the sub-pixel driving circuit arranged in the first display area through a second conductive trace 81;

The area of at least part of the anode of the second display area is smaller than the area of the anode of the sub-pixel of the same color in the first display area.

In this embodiment, the anodes of the first display area and the second display area are set differently, and the area of at least part of the anodes of the second display area (S2/S3/S4) is smaller than the area of the anodes of the same color sub-pixels of the first display area S1. For example, the display substrate includes red sub-pixels, green sub-pixels and blue sub-pixels, and the area of at least part of the anodes of the red sub-pixels of the second display area (S2/S3/S4) is smaller than the area of the anodes of the red sub-pixels of the first display area S1; and/or, the area of at least part of the anodes of the green sub-pixels of the second display area (S2/S3/S4) is smaller than the area of the anodes of the green sub-pixels of the first display area S1. The area of the anode; and/or, the area of at least part of the anode of the blue sub-pixel in the second display area (S2/S3/S4) is smaller than the area of the anode of the blue sub-pixel in the first display area S1; in this way, the area of at least part of the anode in the second display area (S2/S3/S4) can be reduced, so that the area of the whole composed of the first conductive trace 82 and the anode 60 of the second display area (as a plate of the N4 point capacitor of the sub-pixel driving circuit) is reduced, thereby reducing the N4 point capacitor of the sub-pixel driving circuit connected to the light-emitting element of the second display area, so that the brightness of the second display area is close to that of the first display area, thereby ensuring the display effect of the display substrate.

In this embodiment, the second display area (S2/S3/S4) may be provided with a gate driving circuit or a light emitting control circuit.

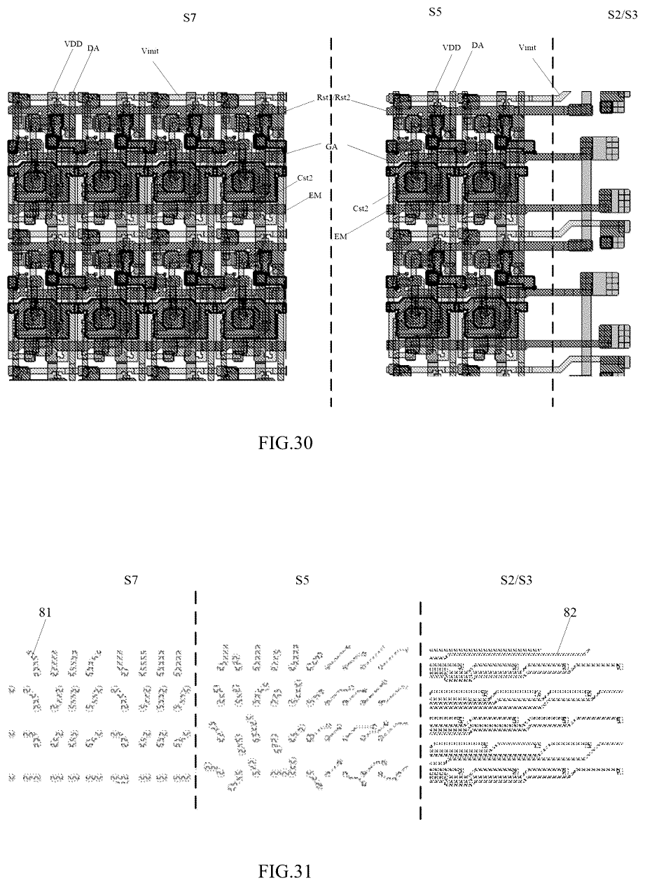

As shown in FIG. 31, the anode of the light emitting element in the first display area is connected to the sub-pixel driving circuit via the second conductive trace 81. Since the sub-pixel driving circuit is provided in the first display area, the distance between the anode of the light emitting element and the sub-pixel driving circuit is relatively short. Therefore, the length of the second conductive trace 81 is shorter than the length of the first conductive trace 82. When the line width of the second conductive trace 81 is substantially the same as the line width of the first conductive trace 82, the area of the second conductive trace 81 is smaller than the area of the first conductive trace 82. In the first display area, the second conductive trace 81 and the anode 60 as a whole serve as a plate of the N4 point capacitor driving the light-emitting unit in the first display area; in the second display area, the first conductive trace 82 and the anode 60 as a whole serve as a plate of the N4 point capacitor driving the light-emitting unit in the second display area; since the area of the second conductive trace 81 is smaller than the area of the first conductive trace 82, when the area of the anode in the first display area and the anode in the second display area are the same, the area of one plate of the N4 point capacitor corresponding to the first display area will be smaller than the area of one plate of the N4 point capacitor corresponding to the second display area, resulting in the N4 point capacitor corresponding to the first display area being smaller than the N4 point capacitor corresponding to the second display area, and a difference occurs between the N4 point capacitors corresponding to the first display area and the second display area, so that the second display area cannot light up or cannot reach the same brightness as the first display area; in this embodiment, by reducing the area of at least part of the anode in the second display area, the purpose of reducing the difference in the N4 point capacitors corresponding to the first display area and the second display area is achieved, so that the brightness of the second display area is close to that of the first display area, thereby ensuring the display effect of the display substrate.

In this embodiment, the area of some anodes in the second display area may be smaller than that of the anodes of the same color sub-pixels in the first display area, or the area of all anodes in the second display area may be smaller than that of the anodes of the same color sub-pixels in the first display area.

In this embodiment, the anode of the sub-pixel with differentially designed area in the first display area and the second display area is called the first anode, that is, for the sub-pixel to which the first anode belongs, the first display area and the second display area have anodes with different areas, and the area of the first anode 601 in the first display area is larger than the area of the first anode 601 of the sub-pixel of the same color in the second display area. In this embodiment, it is worth noting that the comparison of the anode area is limited to the comparison of the anode area of the sub-pixel of the same color.

The sub-pixels include green sub-pixels, red sub-pixels and blue sub-pixels, and the first anode 601 can be the anodes of the green sub-pixels, the red sub-pixels and the blue sub-pixels, that is, the area of the anode of the red sub-pixels in the second display area (S2/S3/S4) is smaller than the area of the anode of the red sub-pixels in the first display area S1; the area of part of the anode of the green sub-pixels in the second display area (S2/S3/S4) is smaller than the area of the anode of the green sub-pixels in the first display area S1; the area of the anode of the blue sub-pixels in the second display area (S2/S3/S4) is smaller than the area of the anode of the blue sub-pixels in the first display area S1; in this way, the area of the anode of the first display area (S2/S3/S4) can be reduced. The capacitance difference at point N4 corresponding to the red sub-pixel in the domain and the red sub-pixel in the second display area can be reduced, so that the brightness of the red sub-pixel in the second display area is close to that of the red sub-pixel in the first display area; the capacitance difference at point N4 corresponding to the green sub-pixel in the first display area and the green sub-pixel in the second display area can be reduced, so that the brightness of the green sub-pixel in the second display area is close to that of the green sub-pixel in the first display area; the capacitance difference at point N4 corresponding to the blue sub-pixel in the first display area and the blue sub-pixel in the second display area can be reduced, so that the brightness of the blue sub-pixel in the second display area is close to that of the blue sub-pixel in the first display area, thereby improving the display effect of the display substrate.

In addition, since the green sub-pixel accounts for the largest proportion of light emission, only the anode of the green sub-pixel can be designed differently, that is, the first anode is the anode of the green sub-pixel, and the area of the partial anode of the green sub-pixel in the second display area (S2/S3/S4) is smaller than the area of the anode of the green sub-pixel in the first display area S1. In this way, the difference in capacitance at point N4 corresponding to the green sub-pixel in the first display area and the green sub-pixel in the second display area can be reduced, so that the brightness of the green sub-pixel in the second display area is close to that of the green sub-pixel in the first display area, thereby improving the display effect of the display substrate.

Of course, it is also possible to only perform a differentiated design on the anode of the red sub-pixel, that is, the first anode is the anode of the red sub-pixel, and the area of the anode of the red sub-pixel in the second display area (S2/S3/S4) is smaller than the area of the anode of the red sub-pixel in the first display area S1. In this way, the difference in capacitance at point N4 corresponding to the red sub-pixel in the first display area and the red sub-pixel in the second display area can be reduced, so that the brightness of the red sub-pixel in the second display area is close to that of the red sub-pixel in the first display area, thereby improving the display effect of the display substrate.

Of course, it is also possible to only design the anode of the blue sub-pixel differently, that is, the first anode is the anode of the blue sub-pixel, and the area of the anode of the blue sub-pixel in the second display area (S2/S3/S4) is smaller than the area of the anode of the blue sub-pixel in the first display area S1. In this way, the difference in capacitance at point N4 corresponding to the blue sub-pixel in the first display area and the blue sub-pixel in the second display area can be reduced, so that the brightness of the blue sub-pixel in the second display area is close to that of the blue sub-pixel in the first display area, thereby improving the display effect of the display substrate.

In some embodiments, in the first display area, the areas of the anodes of sub-pixels of the same color may be the same.

In some embodiments, in the second display area, the areas of the anodes of the sub-pixels of the same color may be the same.

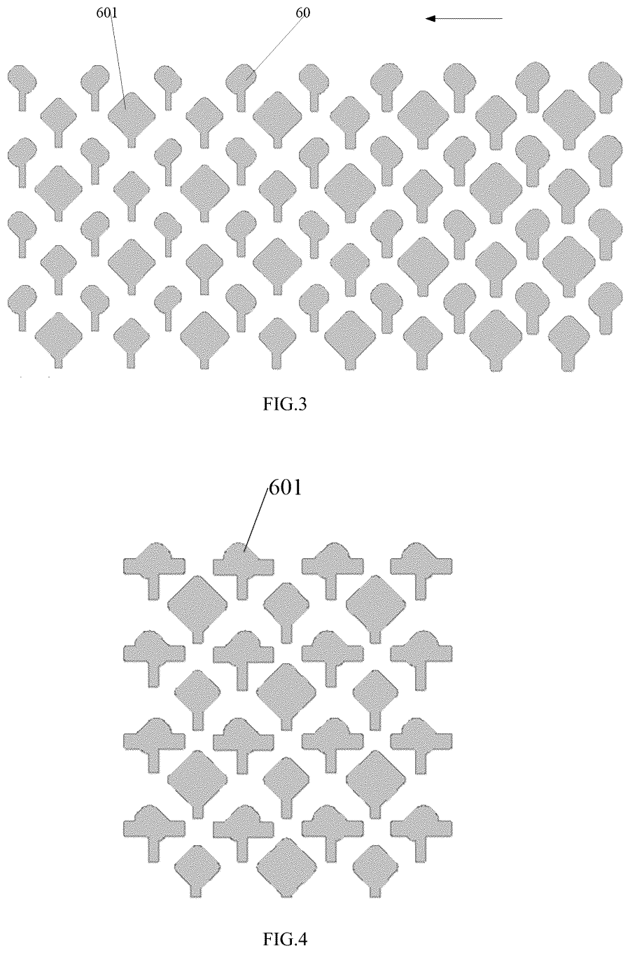

In some embodiments, as shown in FIG. 3, the direction of the arrow is the direction away from the first display area. In the second display area, along the direction indicated by the arrow, the area of the first anode of the same color sub-pixel gradually decreases. For example, along the direction indicated by the arrow, the area of the anode of the green sub-pixel gradually decreases, so that the capacitance difference at the N4 point corresponding to the green sub-pixel in the first display area and the green sub-pixel in the second display area can be gradually reduced, so that the brightness transition of the green sub-pixel in the first display area and the second display area is smooth, thereby ensuring the display effect of the display substrate; for another example, along the direction indicated by the arrow, the area of the anode of the red sub-pixel gradually decreases, so that the capacitance difference at the N4 point corresponding to the red sub-pixel in the first display area and the red sub-pixel in the second display area can be gradually reduced, so that the brightness transition of the red sub-pixel in the first display area and the second display area is smooth, thereby ensuring the display effect of the display substrate; for another example, along the direction indicated by the arrow, the area of the anode of the blue sub-pixel gradually decreases, so that the capacitance difference at the N4 point corresponding to the blue sub-pixel in the first display area and the blue sub-pixel in the second display area can be gradually reduced, so that the brightness transition of the blue sub-pixel in the first display area and the second display area is smooth, thereby ensuring the display effect of the display substrate.

In some embodiments, in the second display area, a plurality of pixel repetition units are arranged in sequence along a direction away from the first display area, the pixel repetition unit includes at least one sub-pixel, and in each of the pixel repetition units, the areas of the first anodes of sub-pixels of the same color are equal; the areas of the first anodes of sub-pixels of the same color in different pixel repetition units gradually decrease, that is, the area of the first anode gradually decreases with the pixel repetition unit as a unit.

Along the direction away from the first display area, the 1st pixel repeating unit, the 2nd pixel repeating unit, the 3rd pixel repeating unit, . . . , the x-th pixel repeating unit are arranged in sequence, the area of the first anode of the (k+1)-th pixel repeating unit is n times the area of the first anode of the same color sub-pixel of the k-th pixel repeating unit, k is a positive integer less than x, and n is less than 1 and greater than 0.

For example, if n is 0.9 and the anode area of the green sub-pixel in the first pixel repeating unit is SG, then the anode areas of the green sub-pixels in the second pixel repeating unit, the third pixel repeating unit, the fourth pixel repeating unit, . . . can be 0.9*SG, 0.81*SG, 0.729*SG, . . . and so on.

For example, if n is 0.8, and the anode area of the red sub-pixel in the first pixel repeating unit is SR, then the anode areas of the red sub-pixels in the second pixel repeating unit, the third pixel repeating unit, the fourth pixel repeating unit, . . . can be 0.8*SR, 0.64*SR, 0.512*SR, . . . , and so on.

For example, if n is 0.9 and the anode area of the blue sub-pixel in the first pixel repeating unit is SB, then the anode areas of the blue sub-pixels in the second pixel repeating unit, the third pixel repeating unit, the fourth pixel repeating unit, . . . may be 0.9*SB, 0.81*SB, 0.729*SB, . . . and so on.

In some embodiments, the difference between the area of the first anode of the (k+1)-th pixel repetition unit and the area of the first anode of the same color sub-pixel of the k-th pixel repetition unit is S1, S1=S/m, S is the area of the first anode of the same color sub-pixel of the 1st pixel repetition unit, and m is an integer greater than 1.

For example, if m is 10, and the anode area of the green sub-pixel in the first pixel repeating unit is SG, then the anode area of the green sub-pixel in the second pixel repeating unit, the third pixel repeating unit, the fourth pixel repeating unit, . . . can be 0.9*SG, 0.8*SG, 0.7*SG, . . . , and so on.

For example, if m is 5, and the anode area of the red sub-pixel in the first pixel repeating unit is SR, then the anode areas of the red sub-pixels in the second pixel repeating unit, the third pixel repeating unit, the fourth pixel repeating unit, . . . can be 0.8*SR, 0.6*SR, 0.4*SR, . . . , and so on.

For example, if m is 10, and the anode area of the blue sub-pixel in the first pixel repeating unit is SB, then the anode areas of the blue sub-pixels in the second pixel repeating unit, the third pixel repeating unit, the fourth pixel repeating unit, . . . can be 0.9*SB, 0.8*SB, 0.7*SB, . . . , and so on.

Each pixel repetition unit may include 2*4 sub-pixels or 1 sub-pixel.

In some embodiments, as shown in FIG. 2, the first display area includes a third display area S7 and a transitional display area (S5/S6), and the transitional display area (S5/S6) is located between the third display area S7 and the second display area (S2/S3/S4); specifically, the transitional display area S5 is located between the second display area S2 and the third display area S7, the transitional display area S5 is located between the second display area S3 and the third display area S7, and the transitional display area S6 is located between the second display area S4 and the third display area S7.

In this embodiment, a transitional display area is provided at the junction of the first display area and the second display area, and the anode of the light-emitting element of the second display area can be connected to the sub-pixel driving circuit provided in the transitional display area through the first conductive trace 82.

In this embodiment, the anode area of the third display area S7 may not be changed, and the anode area of the transitional display area is changed, so that the display brightness transition from the third display area S7 to the second display area (S2/S3/S4) is more natural. The area of at least part of the anode of the transitional display area (S5/1) is smaller than the area of the anode of the same color sub-pixel in the third display area S7, and the area of at least part of the anode of the transitional display area is larger than the area of the anode of the same color sub-pixel in the second display area (S2/S3/S4).

As shown in FIG. 31, the anode of the light emitting element in the third display area is connected to the sub-pixel driving circuit via the second conductive trace 81. Since the sub-pixel driving circuit is provided in the third display area, the distance between the anode of the light emitting element and the sub-pixel driving circuit is relatively short. Therefore, the length of the second conductive trace 81 is shorter than the length of the first conductive trace 82. When the line width of the second conductive trace 81 is substantially the same as the line width of the first conductive trace 82, the area of the second conductive trace 81 is smaller than the area of the first conductive trace 82. In the third display area, the second conductive trace 81 and the anode 60 as a whole serve as a plate of the N4 point capacitor; in the second display area, the first conductive trace 82 and the anode 60 as a whole serve as a plate of the N4 point capacitor; since the area of the second conductive trace 81 is smaller than the area of the first conductive trace 82, when the area of the anode of the third display area and the area of the anode of the second display area are the same, the area of one plate of the N4 point capacitor of the third display area will be smaller than the area of one plate of the N4 point capacitor corresponding to the second display area, resulting in the N4 point capacitor of the third display area being smaller than the N4 point capacitor corresponding to the second display area, and a difference between the N4 point capacitors corresponding to the third display area and the second display area, so that the second display area cannot light up or cannot reach the same brightness as the third display area; in this embodiment, by reducing the area of at least part of the anode of the second display area and the transitional display area, the purpose of reducing the difference in the N4 point capacitor corresponding to the third display area and the second display area is achieved, so that the brightness of the second display area is close to that of the third display area, thereby ensuring the display effect of the display substrate.

In this embodiment, the area of some anodes in the second display area and the transitional display area may be smaller than the area of the anodes of the same color sub-pixels in the third display area, or the area of all anodes in the second display area and the transitional display area may be smaller than the area of the anodes of the same color sub-pixels in the third display area.

In this embodiment, the anode of the sub-pixel with differentially designed area in the transitional display area and the second display area is called the first anode, that is, for the sub-pixel to which the first anode belongs, there are anodes with different areas in the third display area, the transitional display area and the second display area, the area of the first anode 601 in the third display area is larger than the area of the first anode 601 of the sub-pixel of the same color in the transitional display area, and the area of the first anode 601 in the transitional display area is larger than the area of the first anode 601 of the sub-pixel of the same color in the second display area. In this embodiment, it is worth noting that the comparison of the anode area is limited to the comparison of the anode area of the sub-pixel of the same color.

The sub-pixels include a green sub-pixel, a red sub-pixel and a blue sub-pixel, and the first anode 601 can be the anodes of the green sub-pixel, the red sub-pixel and the blue sub-pixel, that is, the area of the anode of the red sub-pixel in the second display area (S2/S3/S4) is smaller than the area of the anode of the red sub-pixel in the transitional display area (S5/S6), and the area of the anode of the red sub-pixel in the transitional display area (S5/S6) is smaller than the area of the anode of the red sub-pixel in the third display area S7; the area of part of the anode of the green sub-pixel in the second display area (S2/S3/S4) is smaller than the area of the anode of the green sub-pixel in the transitional display area (S5/S6), and the area of the anode of the green sub-pixel in the transitional display area (S5/S6) is smaller than the area of the anode of the green sub-pixel in the third display area S7; the area of the anode of the blue sub-pixel in the second display area (S2/S3/S4) is smaller than the area of the anode of the blue sub-pixel in the transitional display area (S5/S6). 6), the area of the anode of the blue sub-pixel in the transitional display area (S5/S6) is smaller than the area of the anode of the blue sub-pixel in the third display area S7; in this way, the capacitance difference at point N4 corresponding to the red sub-pixel in the third display area and the red sub-pixel in the second display area can be gradually reduced, so that the brightness of the red sub-pixel in the third display area is gradually close to that of the red sub-pixel in the second display area; the capacitance difference at point N4 corresponding to the green sub-pixel in the third display area and the green sub-pixel in the second display area can be gradually reduced, so that the brightness of the green sub-pixel in the second display area is gradually close to that of the green sub-pixel in the third display area; the capacitance difference at point N4 corresponding to the blue sub-pixel in the third display area and the blue sub-pixel in the second display area can be gradually reduced, so that the brightness of the blue sub-pixel in the second display area is gradually close to that of the blue sub-pixel in the third display area, thereby improving the display effect of the display substrate.

In addition, since the green sub-pixel accounts for the largest proportion of light emission, only the anode of the green sub-pixel can be designed differently, that is, the first anode is the anode of the green sub-pixel, the area of the anode of the green sub-pixel in the second display area (S2/S3/S4) is smaller than the area of the anode of the green sub-pixel in the transitional display area (S5/S6), and the area of the anode of the green sub-pixel in the transitional display area (S5/S6) is smaller than the area of the anode of the green sub-pixel in the third display area S7. In this way, the difference in capacitance at point N4 corresponding to the green sub-pixel in the third display area and the green sub-pixel in the second display area can be gradually reduced, so that the brightness of the green sub-pixel in the second display area gradually approaches the brightness of the green sub-pixel in the third display area, thereby improving the display effect of the display substrate.

Of course, it is also possible to only design a differentiated design for the anode of the red sub-pixel, that is, the first anode is the anode of the red sub-pixel, the area of the anode of the red sub-pixel in the second display area (S2/S3/S4) is smaller than the area of the anode of the red sub-pixel in the transitional display area (S5/S6), and the area of the anode of the red sub-pixel in the transitional display area (S5/S6) is smaller than the area of the anode of the red sub-pixel in the third display area S7. In this way, the difference in capacitance at point N4 corresponding to the red sub-pixel in the third display area and the red sub-pixel in the second display area can be gradually reduced, so that the brightness of the red sub-pixel in the second display area is gradually close to the brightness of the red sub-pixel in the third display area, thereby improving the display effect of the display substrate.

Of course, it is also possible to only perform a differentiated design on the anode of the blue sub-pixel, that is, the first anode is the anode of the blue sub-pixel, the area of the anode of the blue sub-pixel in the second display area (S2/S3/S4) is smaller than the area of the anode of the blue sub-pixel in the transitional display area (S5/S6), and the area of the anode of the blue sub-pixel in the transitional display area (S5/S6) is smaller than the area of the anode of the blue sub-pixel in the third display area S7. In this way, the difference in capacitance at point N4 corresponding to the blue sub-pixel in the third display area and the blue sub-pixel in the second display area can be gradually reduced, so that the brightness of the blue sub-pixel in the second display area gradually approaches the brightness of the blue sub-pixel in the third display area, thereby improving the display effect of the display substrate.

In some embodiments, in the third display area, the areas of the anodes of the sub-pixels of the same color may be the same.

In some embodiments, in the second display area, the areas of the anodes of the sub-pixels of the same color may be the same.

In some embodiments, in the transitional display area, the areas of the anodes of sub-pixels of the same color may be the same.

In some embodiments, in the transitional display area and the second display area, the area of the first anode of the same color sub-pixel gradually decreases along the direction away from the third display area. For example, along the direction away from the third display area, the area of the anode of the green sub-pixel gradually decreases, so that the capacitance difference of the N4 point corresponding to the green sub-pixel in the third display area and the green sub-pixel in the second display area can be gradually reduced, so that the brightness transition of the green sub-pixel in the third display area and the second display area is smooth, ensuring the display effect of the display substrate; for another example, along the direction away from the third display area, the area of the anode of the blue sub-pixel gradually decreases, so that the capacitance difference of the N4 point corresponding to the blue sub-pixel in the third display area and the blue sub-pixel in the second display area can be gradually reduced, so that the brightness transition of the blue sub-pixel in the third display area and the second display area is smooth, ensuring the display effect of the display substrate; for another example, along the direction away from the third display area, the area of the anode of the red sub-pixel gradually decreases, so that the capacitance difference of the N4 point corresponding to the red sub-pixel in the third display area and the red sub-pixel in the second display area can be gradually reduced, so that the brightness transition of the red sub-pixel in the third display area and the second display area is smooth, ensuring the display effect of the display substrate.

In some embodiments, in the transitional display area and the second display area, a plurality of pixel repetition units are sequentially arranged along a direction away from the third display area, the pixel repetition unit includes at least one sub-pixel, and in each of the pixel repetition units, the areas of the first anodes of sub-pixels of the same color are equal; the areas of the first anodes of sub-pixels of the same color in different pixel repetition units gradually decrease, that is, the area of the first anode gradually decreases with the pixel repetition unit as a unit.

Along the direction away from the third display area, the 1st pixel repeating unit, the 2nd pixel repeating unit, the 3rd pixel repeating unit, . . . , the x-th pixel repeating unit are arranged in sequence, the area of the first anode of the (k+1)-th pixel repeating unit is n times the area of the first anode of the same color sub-pixel of the k-th pixel repeating unit, k is a positive integer less than x, and n is less than 1 and greater than 0.

For example, if n is 0.9 and the anode area of the green sub-pixel in the first pixel repeating unit is SG, then the anode areas of the green sub-pixels in the second pixel repeating unit, the third pixel repeating unit, the fourth pixel repeating unit, . . . can be 0.9*SG, 0.81*SG, 0.729*SG, . . . and so on.

For example, if n is 0.8, and the anode area of the red sub-pixel in the first pixel repeating unit is SR, then the anode areas of the red sub-pixels in the second pixel repeating unit, the third pixel repeating unit, the fourth pixel repeating unit, . . . can be 0.8*SR, 0.64*SR, 0.512*SR, . . . , and so on.

For example, if n is 0.9 and the anode area of the blue sub-pixel in the first pixel repeating unit is SB, then the anode areas of the blue sub-pixels in the second pixel repeating unit, the third pixel repeating unit, the fourth pixel repeating unit, . . . may be 0.9*SB, 0.81*SB, 0.729*SB, . . . and so on.

A difference between the area of the first anode of the (k+1)-th pixel repetition unit and the area of the first anode of the same color sub-pixel of the k-th pixel repetition unit is S1, S1=S/m, S is the area of the first anode of the same color sub-pixel of the 1st pixel repetition unit, and m is an integer greater than 1.

For example, if m is 10, and the anode area of the green sub-pixel in the first pixel repeating unit is SG, then the anode area of the green sub-pixel in the second pixel repeating unit, the third pixel repeating unit, the fourth pixel repeating unit, . . . can be 0.9*SG, 0.8*SG, 0.7*SG, . . . , and so on.

For example, if m is 5, and the anode area of the red sub-pixel in the first pixel repeating unit is SR, then the anode areas of the red sub-pixels in the second pixel repeating unit, the third pixel repeating unit, the fourth pixel repeating unit, . . . can be 0.8*SR, 0.6*SR, 0.4*SR, . . . , and so on.

For example, if m is 10, and the anode area of the blue sub-pixel in the first pixel repeating unit is SB, then the anode areas of the blue sub-pixels in the second pixel repeating unit, the third pixel repeating unit, the fourth pixel repeating unit, . . . can be 0.9*SB, 0.8*SB, 0.7*SB, . . . , and so on.

Each pixel repetition unit may include 2*4 sub-pixels or 1 sub-pixel.

In some embodiments, the sub-pixels in the third display area may be real sub-pixels or sub-pixel rendering (SPR) algorithm sub-pixels.

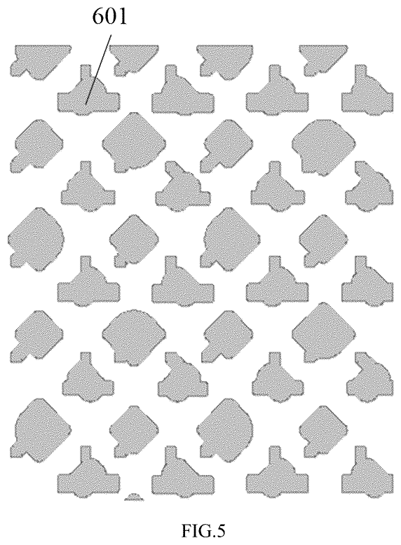

In this embodiment, the pattern of the first anode can be a regular pattern or an irregular pattern. As shown in FIGS. 4 and 5, the pattern of the first anode 601 can be a combination of at least one sub-pattern, and the sub-pattern includes but is not limited to a circle, an ellipse, a rectangle and an irregular pattern.

In this embodiment, as shown in FIG. 31, the anode of the light emitting element in the first display area is connected to the sub-pixel driving circuit through the second conductive trace 81, and the anode of the light emitting element in the second display area is connected to the sub-pixel driving circuit through the first conductive trace 82. Since the sub-pixel driving circuit is provided in the first display area, the distance between the anode of the light emitting element and the sub-pixel driving circuit is relatively short, so the length of the second conductive trace 81 is less than the length of the first conductive trace 82. In the first display area, the second conductive trace 81 and the anode 60 as a whole serve as a plate of the N4 point capacitor; in the second display area, the first conductive trace 82 and the anode 60 as a whole serve as a plate of the N4 point capacitor; in order to reduce the difference in the N4 point capacitance corresponding to the first display area and the second display area, the line width of the second conductive trace 81 can be widened, so that the line width of the second conductive trace 81 is greater than the line width of the first conductive trace 82, and the area of the second conductive trace 81 is as close to the area of the first conductive trace 82 as possible, or equal to the area of the first conductive trace 82. In some embodiments, the area of the orthographic projection of the first conductive trace 82 connected to the light-emitting element of the sub-pixel with the first luminous color on the substrate is equal to the area of the orthographic projection of the second conductive trace 81 connected to the light-emitting element of the sub-pixel with the same luminous color on the substrate. In this way, the area of one plate of the N4 point capacitor corresponding to the first display area can be close to the area of one plate of the N4 point capacitor corresponding to the second display area, or equal to the area of one plate of the N4 point capacitor corresponding to the second display area, so as to reduce the difference between the N4 point capacitors corresponding to the first display area and the second display area, so that the brightness of the second display area is close to that of the first display area, and the display effect of the display substrate is guaranteed.

In some embodiments, the difference between the sum of the areas of the orthographic projections of the anode of the sub-pixel with the first luminous color and the corresponding first conductive trace on the substrate and the sum of the areas of the orthographic projections of the anode of the sub-pixel with the same luminous color and the corresponding second conductive trace on the substrate is within 10%. For example, the area of the orthographic projections of the anode of the sub-pixel with the first luminous color and the corresponding first conductive trace on the substrate is S11, and the area of the orthographic projections of the anode of the sub-pixel with the same luminous color and the corresponding second conductive trace on the substrate is between 0.9*S11-1.1*S11, so that the area of one plate of the N4 point capacitor corresponding to the first display area can be close to the area of one plate of the N4 point capacitor corresponding to the second display area, so as to reduce the difference between the N4 point capacitors corresponding to the first display area and the second display area, so that the brightness of the second display area is close to that of the first display area, and the display effect of the display substrate is guaranteed.

In this embodiment, in order to reduce the impact on display, the first conductive trace 82 and the second conductive trace 81 are transparent.

The anode may adopt an ITO/Ag/ITO structure, the first conductive trace 82 may adopt ITO, and the anode of the second display area may be an integrated structure with the first conductive trace 82.

In some embodiments, the width of the second display area in a direction perpendicular to its own extension direction may be 1-3 mm, which can maximize the area of the first display area and ensure the display effect of the display substrate.

In this embodiment, as shown in FIG. 6 to FIG. 35, the display substrate includes a plurality of power lines VDD, a plurality of light emitting control lines EM, a plurality of gate lines GA, a plurality of data lines DA, a plurality of reset lines Rst1/Rst2, and a plurality of initialization signal lines Vinit;

Exemplarily, the display substrate includes a plurality of sub-pixels, and the plurality of sub-pixel driving circuits included in the plurality of sub-pixels are distributed in an array. The plurality of sub-pixel driving circuits are divided into a plurality of rows of sub-pixel driving circuits and a plurality of columns of sub-pixel driving circuits. The plurality of rows of sub-pixel driving circuits are arranged along a first direction, and each row of sub-pixel driving circuits includes a plurality of sub-pixel driving circuits arranged along a second direction. The plurality of columns of sub-pixel driving circuits are arranged along a second direction, and each column of sub-pixel driving circuits includes a plurality of sub-pixel driving circuits arranged along the first direction. Exemplarily, the first direction and the second direction intersect. For example, the first direction includes a longitudinal direction, and the second direction includes a transverse direction.

Exemplarily, the sub-pixel includes a sub-pixel driving circuit and a light-emitting element. The sub-pixel driving circuit is coupled to an anode of the light-emitting element and is used to provide a driving signal to the light-emitting element to drive the light-emitting element to emit light.

Exemplarily, the above sub-pixel driving circuit may adopt 7TIC (i.e., 7 transistors and one capacitor), but is not limited thereto.

Exemplarily, the sub-pixel driving circuit includes: a storage capacitor Cst, a first reset transistor T1, a data writing transistor T4, a power control transistor T5, a light emitting control transistor T6, a second reset transistor T7, a driving transistor T3 and a compensation transistor T2;

The compensation transistor T2 includes an active layer 21 and a gate, the driving transistor T3 includes an active layer 22 and a gate, the first electrode of the compensation transistor T2 is coupled to the second electrode of the driving transistor T3, and the second electrode of the compensation transistor T2 is coupled to the gate of the driving transistor T3; the driving transistor T3 is used to drive the light-emitting element to emit light, and the first electrode of the driving transistor T3 is connected to the anode;

The first reset transistor T1 includes a first reset active layer 20 and a gate, the gate of the first reset transistor T1 is coupled to the corresponding reset line Rst1, the first electrode of the first reset transistor T1 is coupled to the corresponding initialization signal line Vinit, and the second electrode of the first reset transistor T1 is coupled to the gate of the driving transistor T3;

The data writing transistor T4 includes a data writing active layer 23 and a gate, the gate of the data writing transistor T4 is coupled to the corresponding gate line GA, the first electrode of the data writing transistor T4 is coupled to the corresponding data line DA, and the second electrode of the data writing transistor T4 is coupled to the first electrode of the driving transistor T3;

The power control transistor T5 includes a power control active layer 24 and a gate, the gate of the power control transistor T5 is coupled to the corresponding light emitting control line EM, the first electrode of the power control transistor T5 is coupled to the corresponding power line VDD, and the second electrode of the power control transistor T5 is coupled to the first electrode of the driving transistor T3;

The light emitting control transistor T6 includes a light emitting control active layer 25 and a gate, the gate of the light emitting control transistor T6 is coupled to the corresponding light emitting control line EM, the first electrode of the light emitting control transistor T6 is coupled to the second electrode of the driving transistor T3, and the second electrode of the light emitting control transistor T6 is coupled to the corresponding light emitting element;

The second reset transistor T7 includes a second reset active layer 26 and a gate, the gate of the second reset transistor T7 is coupled to the corresponding reset line Rst2, the first electrode of the second reset transistor T7 is coupled to the corresponding initialization signal line Vinit, and the second electrode of the second reset transistor T7 is coupled to the corresponding light emitting element.

Exemplarily, the coupling point between the second electrode of the light emitting control transistor T6 and the corresponding light emitting element forms an N4 node.

The first plate Cst1 of the storage capacitor Cst is coupled to the gate T3-g of the driving transistor T3, and the second plate Cst2 of the storage capacitor Cst is coupled to the corresponding power line VDD.

Exemplarily, the plurality of light emitting control lines EM correspond one-to-one to a plurality of rows of sub-pixel driving circuits, and the light emitting control line EM is respectively coupled to each sub-pixel driving circuit in a corresponding row of sub-pixel driving circuits. The light emitting control line EM includes at least a portion extending along the second direction.

Exemplarily, the plurality of gate lines GA correspond one-to-one to a plurality of rows of sub-pixel driving circuits, and the gate line GA is respectively coupled to each sub-pixel driving circuit in a corresponding row of sub-pixel driving circuits. The gate line GA includes at least a portion extending along the second direction.

Exemplarily, the plurality of data lines DA correspond one-to-one to a plurality of columns of sub-pixel driving circuits, and the data line DA is respectively coupled to each sub-pixel driving circuit in a corresponding column of sub-pixel driving circuits. The data line DA includes at least a portion extending along the first direction.

Exemplarily, the plurality of reset lines Rst1 correspond one-to-one to a plurality of rows of sub-pixel driving circuits, and the reset line Rst1 is respectively coupled to each sub-pixel driving circuit in a corresponding row of sub-pixel driving circuits. The reset line Rst1 includes at least a portion extending along the second direction.

Exemplarily, the plurality of reset lines Rst2 correspond one-to-one to a plurality of rows of sub-pixel driving circuits, and the reset line Rst2 is respectively coupled to each sub-pixel driving circuit in a corresponding row of sub-pixel driving circuits. The reset line Rst2 includes at least a portion extending along the second direction.

Exemplarily, the multiple initialization signal lines Vinit correspond one-to-one to the multiple rows of sub-pixel driving circuits, and the initialization signal line Vinit is respectively coupled to each sub-pixel driving circuit in a corresponding row of sub-pixel driving circuits. The multiple initialization signal lines Vinit include at least a portion extending along the second direction.

In some embodiments, the display substrate includes a first metal layer and a second metal layer located on a side of the first metal layer away from the substrate, the first metal layer includes the initialization signal line and the node connection line, the node connection line connects the gate of the driving transistor and the drain of the compensation transistor, the second metal layer includes a shielding pattern, the shielding pattern is connected to the initialization signal line through a via, and the orthographic projection of the initialization signal line on the substrate overlaps at least partially with the orthographic projection of the node connection line on the substrate. In this way, the shielding pattern can have a shielding effect on the gate of the driving transistor, and the stability of the driving transistor can be ensured.

In some embodiments, the first metal layer further includes a first adapter block and a second adapter block, the second metal layer further includes a third adapter block, the drain of the light-emitting control transistor is connected to the first adapter block, the drain of the second reset transistor is connected to the second adapter block, the first adapter block and the second adapter block are connected through the third adapter block, and the third adapter block is connected to the anode.

When the sub-pixel driving circuit of the above structure is working, each working cycle includes a reset period, a writing compensation period and a light emitting period.

During the reset period, the reset signal input by the reset line Rst1 is at a valid level, the first reset transistor T1 is turned on, and the initialization signal transmitted by the initialization signal line Vinit is input to the gate T3-g of the driving transistor T3, so that the gate-source voltage Vgs maintained on the driving transistor T3 in the previous frame is cleared, thereby resetting the gate T3-g of the driving transistor T3.

During the writing compensation period, the reset signal is at a non-valid level, the first reset transistor T1 is turned off, the gate scanning signal input by the gate line GA is at a valid level, the compensation transistor T2 and the data writing transistor T4 are controlled to be turned on, the data line DA writes the data signal, and transmits it to the first electrode of the driving transistor T3 through the data writing transistor T4. At the same time, the compensation transistor T2 and the data writing transistor T4 are turned on, so that the driving transistor T3 forms a diode structure. Therefore, the threshold voltage compensation of the driving transistor T3 is achieved through the cooperation of the compensation transistor T2, the driving transistor T3 and the data writing transistor T4. When the compensation time is long enough, the gate T3-g potential of the driving transistor T3 can be controlled to finally reach Vdata+Vth, where Vdata represents the data signal voltage value, and Vth represents the threshold voltage of the driving transistor T3.

The reset line Rst2 is at an effective level, controlling the second reset transistor T7 to be turned on, inputting the initialization signal input by the initialization signal line Vinit to the anode of the light emitting element EL, initializing the anode, and controlling the light emitting element EL not to emit light.

During the light-emitting period, the light-emitting control signal written into the light-emitting control line EM is at an effective level, and the power supply control transistor T5 and the light-emitting control transistor T6 are controlled to be turned on, so that the power supply signal transmitted by the power supply line VDD is input to the first electrode of the driving transistor T3. At the same time, since the gate T3-g of the driving transistor T3 is maintained at Vdata+Vth, the driving transistor T3 is turned on, and the gate-source voltage corresponding to the driving transistor T3 is Vdata+Vth−VDD, where VDD is the voltage value corresponding to the power supply signal, and the leakage current generated based on the gate-source voltage flows to the anode of the corresponding light-emitting element EL, driving the corresponding light-emitting element EL to emit light. The cathode of the light-emitting element EL is connected to the negative power supply signal VSS.

The display substrate provided in the above embodiment includes: a semiconductor layer, a first gate insulating layer GI1, a first gate metal layer, a second gate insulating layer GI2, a second gate metal layer, an interlayer insulating layer ILD, a first source-drain metal layer, a first flat layer PLN1, a second source-drain metal layer, a second flat layer PLN2, an ITO layer, a third flat layer, an anode layer, a pixel defining layer, a light-emitting functional layer, a cathode layer and an encapsulation layer, which are sequentially stacked on the substrate in a direction away from the substrate. The display substrate may also include a passivation layer.

7 to 21 are schematic diagrams of film layers of the third display area S7, the transitional display area S6, and the second display area S4 of the embodiment of the present disclosure.

As shown in FIG. 7, the semiconductor layer is used to form: a first reset active layer 20 included in the first reset transistor T1, an active layer 21 included in the compensation transistor T2, an active layer 22 included in the driving transistor T3, a data writing active layer 23 included in the data writing transistor T4, a power control active layer 24 included in the power control transistor T5, a light emission control active layer 25 included in the light emission control transistor T6, a second reset active layer 26 included in the second reset transistor T7, and some conductive structures. where no semiconductor layer is provided in the second display area S4.

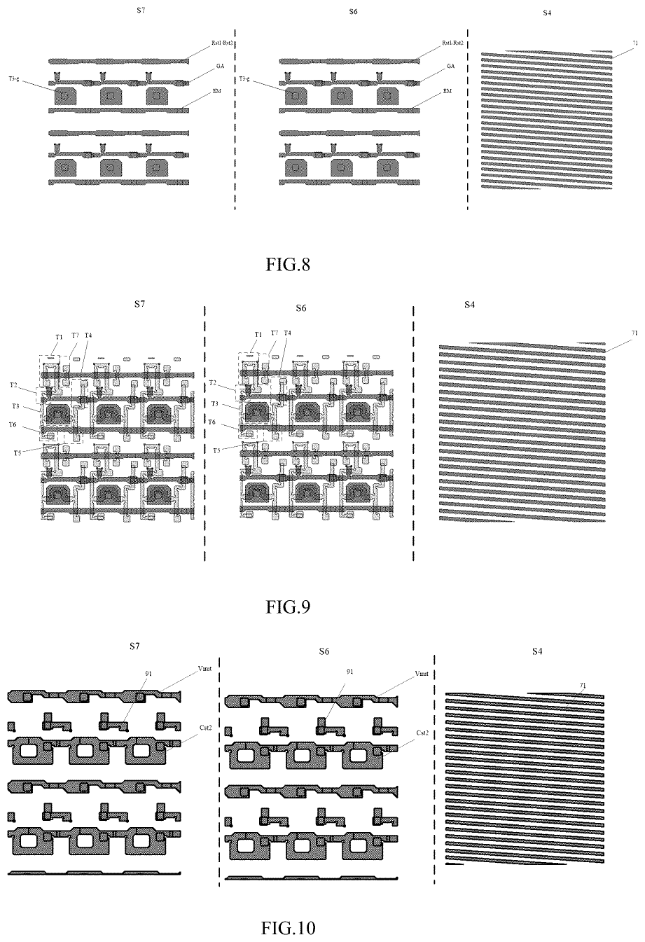

As shown in FIGS. 8 and 9, in the third display area S7 and the transitional display area S6, the first gate metal layer is used to form: the reset line Rst1/Rst2, the gate line GA and the light emitting control line EM, and the gates of each transistor. In the second display area S4, the first gate metal layer is used to form a data fan-out line 71 connected to DA.

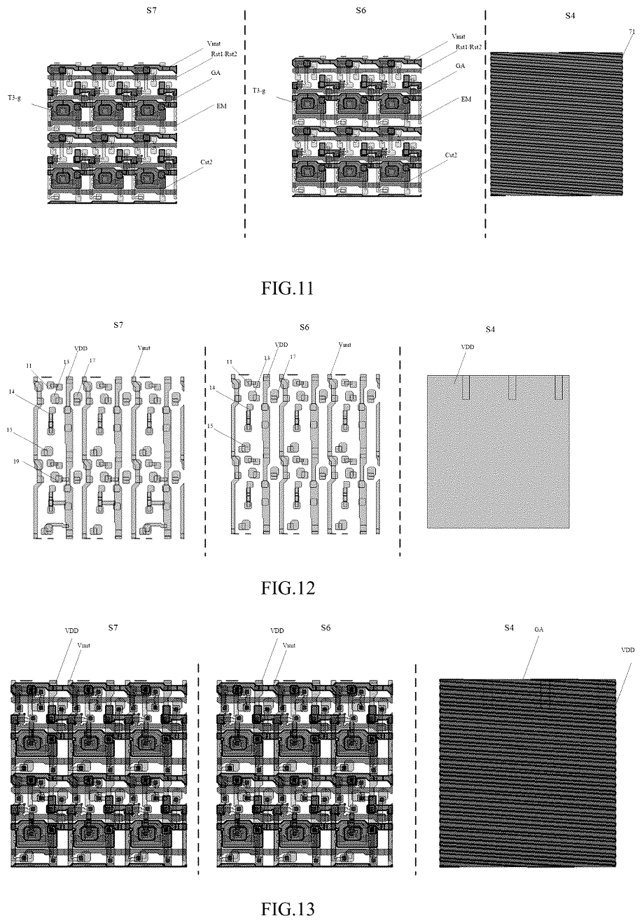

As shown in FIGS. 10 and 11, in the third display area S7 and the transitional display area S6, the second gate metal layer is used to form: the initialization signal line Vinit, the shielding pattern 91, and the second plate Cst2 of the storage capacitor Cst. In the second display area S4, the second gate metal layer is used to form a data fan-out line 71 connected to DA.

The orthographic projection of the shielding pattern 91 on the substrate at least partially overlaps with the orthographic projection of the active layer 21 of the compensation transistor T2 on the substrate. The shielding pattern 91 is connected to the power line VDD.

In the display substrate provided in the above embodiment, the shielding pattern 91 is arranged to have an orthographic projection on the substrate that at least partially overlaps with the orthographic projection of the active layer 21 of the compensation transistor T2 on the substrate, so that the shielding pattern 91 has a shielding effect on the active layer 21 of the compensation transistor T2, which can ensure the stability of the active layer 21 of the compensation transistor T2, thereby facilitating the improvement of the stability of the compensation transistor T2.

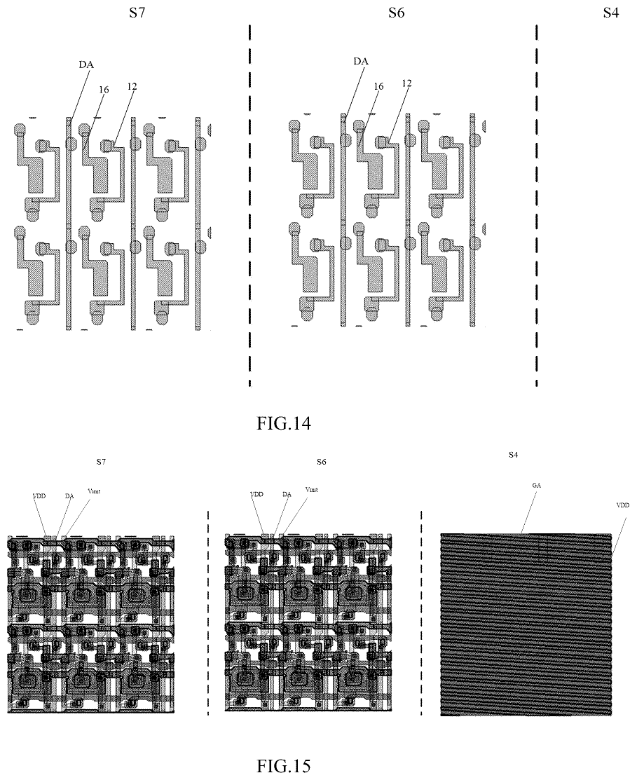

As shown in FIG. 12 and FIG. 13, in the third display area S7 and the transitional display area S6, the first source-drain metal layer (i.e., the first metal layer) is used to form: the power line VDD, the initialization signal line Vinit, the first conductive connection part 11, the third conductive connection part 13, the fourth conductive connection part 14, the fifth conductive connection part 15 and the seventh conductive connection part 17. Among them, the first conductive connection part 11 is used to couple the first electrode of the second reset transistor T7 and the initialization signal line Vinit. The third conductive connection part 13 (including the first adapter block and the second adapter block) is connected to the second conductive connection part 12, and together with the second conductive connection part 12, couples the second electrode of the light-emitting control transistor T6 and the anode of the light-emitting element, and couples the second electrode of the second reset transistor T7 and the anode of the light-emitting element. The fourth conductive connection part 14 (i.e., the node connection line) is used to couple the second electrode of the first reset transistor T1 and the gate of the driving transistor T3, and couples the second electrode of the compensation transistor T2 and the gate of the driving transistor T3. The fifth conductive connection portion 15 is used to couple the second conductive connection portion 12 and the second electrode of the light emitting control transistor T6. The seventh conductive connection portion 17 is used to couple the first electrode of the data writing transistor T4 and the data line DA. In the second display area S4, the first source-drain metal layer is used to form a power line VDD.

As shown in FIG. 12, the first source-drain metal layer is also used to form a ninth conductive connection portion 19 for connecting to a row of virtual pixels to prevent the row of virtual pixels from floating.

As shown in FIG. 14 and FIG. 15, in the third display area S7 and the transitional display area S6, the second source-drain metal layer (i.e., the second metal layer) is used to form: the data line DA, the second conductive connection portion 12 (i.e., the third adapter block) and the shielding pattern 16 (i.e., the shielding pattern included in the second metal layer). The shielding pattern 16 is coupled to the initialization signal line Vinit, and the orthographic projection of the shielding pattern 16 on the substrate at least partially overlaps with the orthographic projection of the gate T3-g of the driving transistor T3 on the substrate, so that the shielding pattern 16 has a shielding effect on the gate T3-g of the driving transistor T3, shielding the electrical signal transmitted on the ITO layer, and can ensure the stability of the driving transistor T3 and the stability of the voltage of the NI node. In the second display area S4, the second source-drain metal layer is not provided.

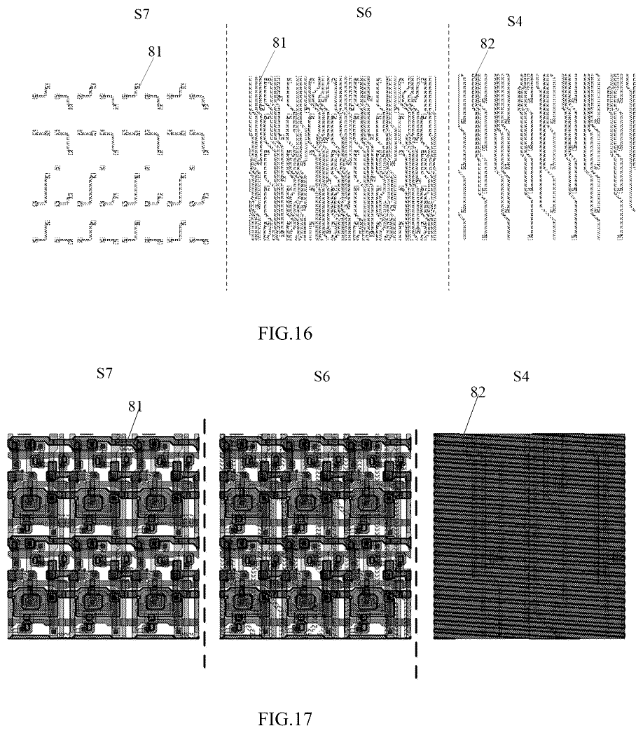

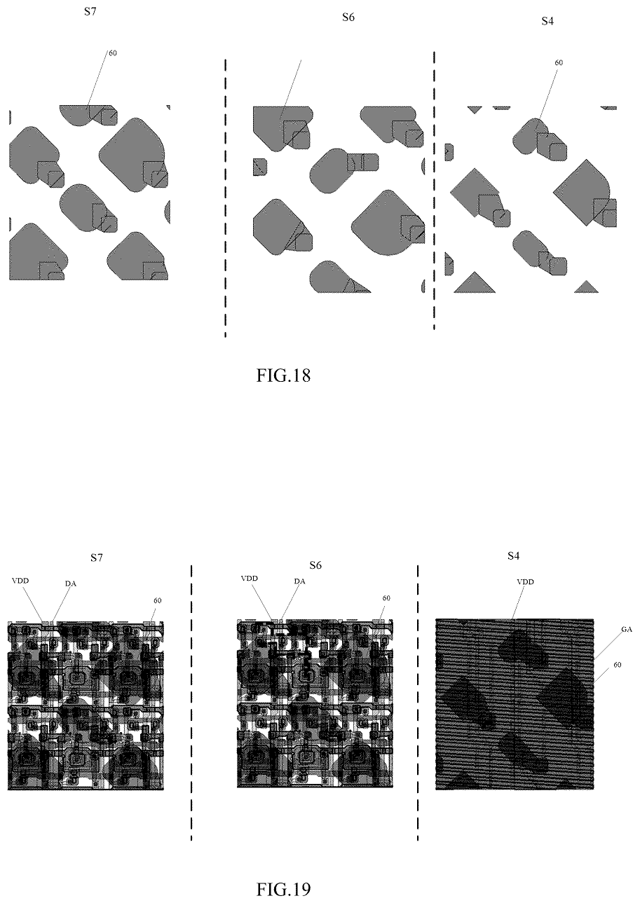

As shown in FIG. 16 and FIG. 17, in the third display area S7 and the transitional display area S6, the ITO layer is used to form the second conductive trace 81. In the second display area S4, the ITO layer is used to form the first conductive trace 82.

As shown in FIG. 18 and FIG. 19, in the third display area S7, the transitional display area S6, and the second display area S4, the anode layer is used to form the anode 60 of the light emitting element.

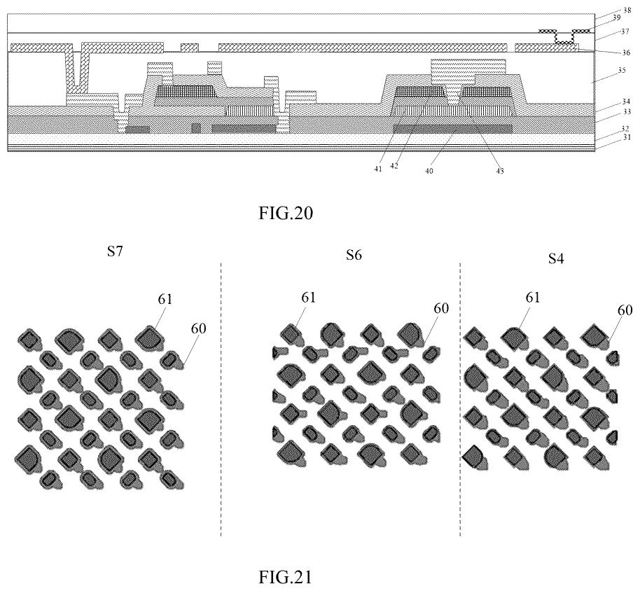

FIG. 20 is a schematic cross-sectional view in the direction of the black dotted line in FIG. 19. As shown in FIG. 20, the display substrate includes a substrate 31, a flexible substrate 32, a semiconductor layer 40, a gate insulating layer 33, a first gate metal layer 41, a second gate metal layer 42, an interlayer insulating layer 34, a first source-drain metal layer 43, a first planar layer 35, a second source-drain metal layer 36, a second planar layer 37, an ITO layer 39, and a third planar layer 38. The substrate 31 and the flexible substrate 32 constitute a base.

As shown in FIG. 21, it is a schematic diagram of the stacking of the pixel defining layer and the anode layer, where 61 is the opening of the pixel defining layer. It can be seen that the size of the opening 61 of the pixel defining layer of the second display area S4 can be the same as the size of the opening 61 of the transitional display area S6, and the area of the anode 60 of the second display area S4 is larger than the area of the anode 60 of the transitional display area S6.

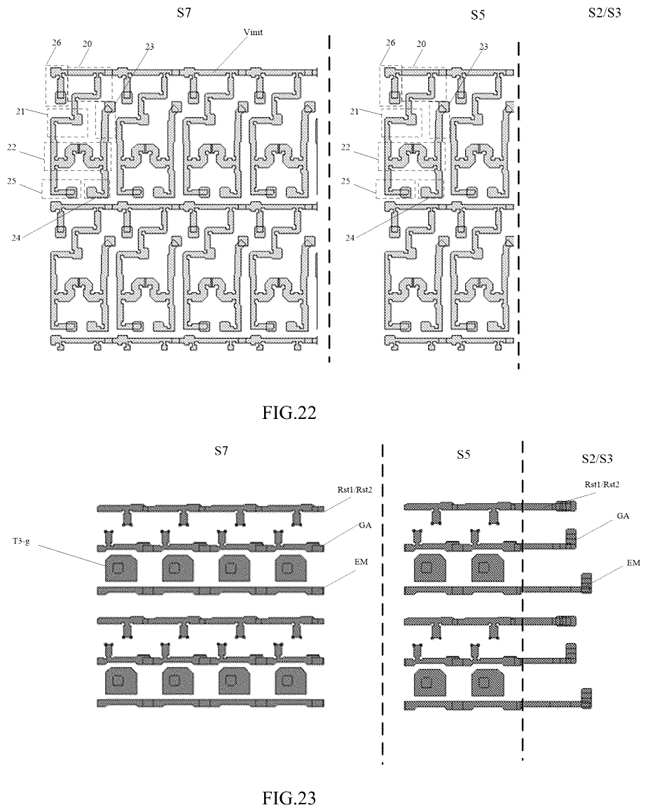

FIGS. 22 to 35 are schematic diagrams of the film layers of the third display area S7, the transitional display area S5 and the second display area S2/S3 of the embodiment of the present disclosure.

As shown in FIG. 22, the semiconductor layer is used to form: a first reset active layer 20 included in the first reset transistor T1, an active layer 21 included in the compensation transistor T2, an active layer 22 included in the driving transistor T3, a data writing active layer 23 included in the data writing transistor T4, a power control active layer 24 included in the power control transistor T5, a light emission control active layer 25 included in the light emission control transistor T6, a second reset active layer 26 included in the second reset transistor T7, and some conductive structures, including the initialization signal line Vinit, and no semiconductor layer is provided in the second display area S2/S3.

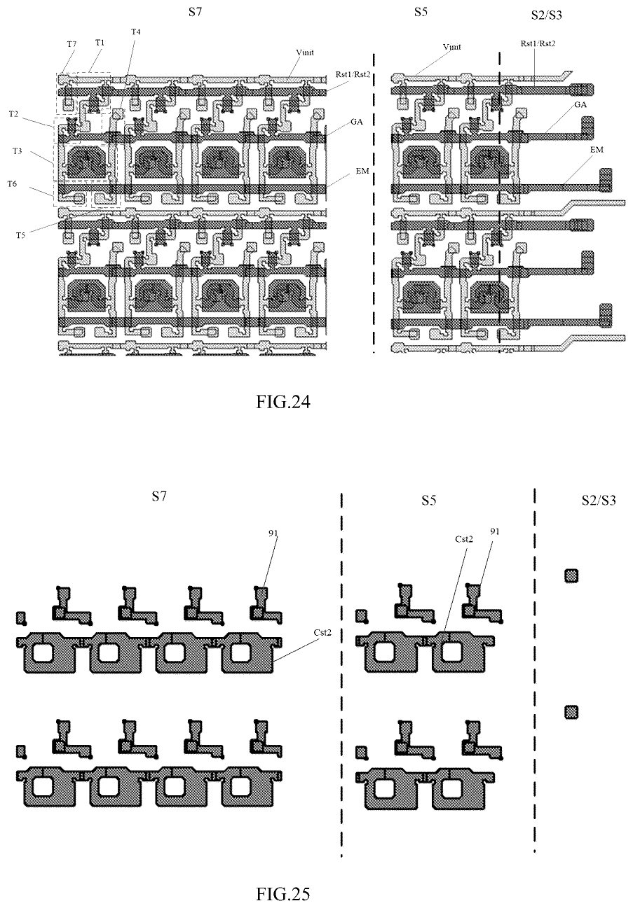

As shown in FIGS. 23 and 24, in the third display area S7, the transitional display area S5 and the second display area S2/S3, the first gate metal layer is used to form: the reset line Rst1/Rst2, the gate line GA and the light emitting control line EM, and the gates of each transistor.

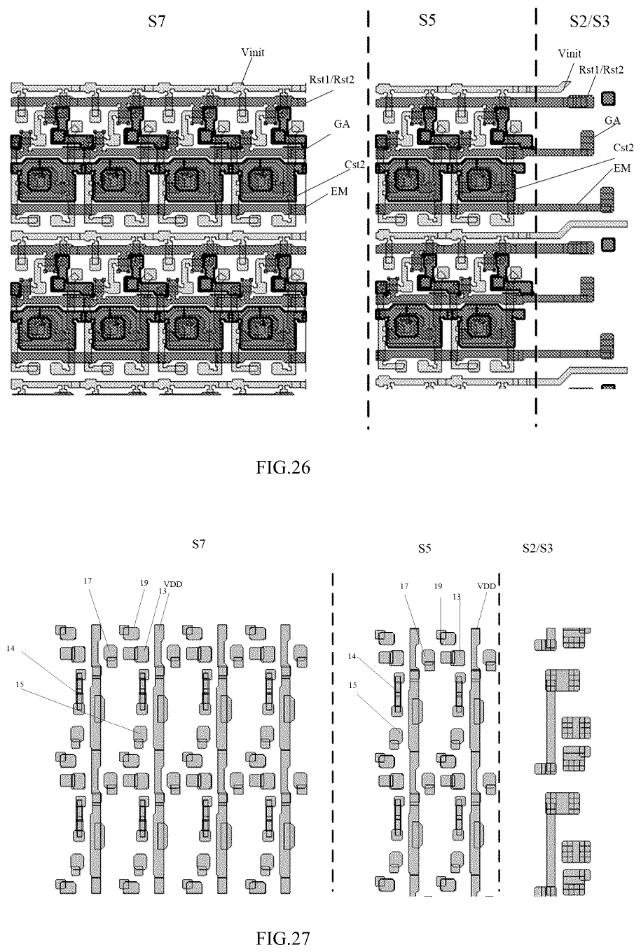

As shown in FIG. 25 and FIG. 26, in the third display area S7 and the transitional display area S5, the second gate metal layer is used to form: a shielding pattern 91, and a second electrode plate Cst2 of the storage capacitor Cst.

The orthographic projection of the shielding pattern 91 on the substrate at least partially overlaps with the orthographic projection of the active layer 21 of the compensation transistor T2 on the substrate. The shielding pattern 91 is connected to the power line VDD.

In the display substrate provided in the above embodiment, the shielding pattern 91 is arranged to have an orthographic projection on the substrate that at least partially overlaps with the orthographic projection of the active layer 21 of the compensation transistor T2 on the substrate, so that the shielding pattern 91 has a shielding effect on the active layer 21 of the compensation transistor T2, which can ensure the stability of the active layer 21 of the compensation transistor T2, thereby facilitating the improvement of the stability of the compensation transistor T2.

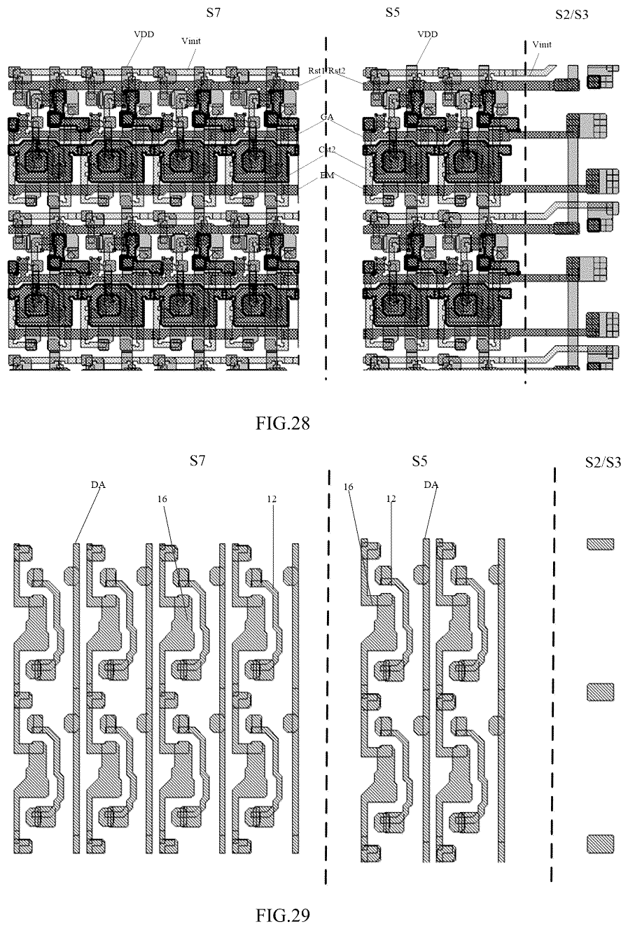

As shown in FIG. 27 and FIG. 28, in the third display area S7 and the transitional display area S5, the first source-drain metal layer (i.e., the first metal layer) is used to form: the power line VDD, the third conductive connection part 13, the fourth conductive connection part 14, the fifth conductive connection part 15, the seventh conductive connection part 17 and the ninth conductive connection part 19. Among them, the third conductive connection part 13 (including the first adapter block and the second adapter block) is connected to the second conductive connection part 12, and the second electrode of the light-emitting control transistor T6 is coupled with the anode of the light-emitting element together with the second conductive connection part 12, and the second electrode of the second reset transistor T7 is coupled with the anode of the light-emitting element. The fourth conductive connection part 14 (i.e., the node connection line) is used to couple the second electrode of the first reset transistor T1 and the gate of the driving transistor T3, and the second electrode of the compensation transistor T2 and the gate of the driving transistor T3. The fifth conductive connection part 15 is used to couple the second conductive connection part 12 and the second electrode of the light-emitting control transistor T6. The seventh conductive connection part 17 is used to couple the first electrode of the data writing transistor T4 and the data line DA. The ninth conductive connection portion 19 is used to couple the initialization signal line Vinit and the shielding pattern 16.

As shown in FIG. 29 and FIG. 30, in the third display area S7 and the transitional display area S5, the second source-drain metal layer (i.e., the second metal layer) is used to form: the data line DA, the second conductive connection portion 12 (i.e., the third adapter block) and the shielding pattern 16 (i.e., the shielding pattern included in the second metal layer). The shielding pattern 16 is coupled to the initialization signal line Vinit, and the orthographic projection of the shielding pattern 16 on the substrate at least partially overlaps with the orthographic projection of the gate T3-g of the driving transistor T3 on the substrate, so that the shielding pattern 16 has a shielding effect on the gate T3-g of the driving transistor T3, and can ensure the stability of the driving transistor T3.

As shown in FIG. 31, in the third display area S7 and the transitional display area S5, the ITO layer is used to form the second conductive trace 81. In the second display area S2/S3, the ITO layer is used to form the first conductive trace 82. It can be seen that the length of the first conductive trace 82 is greater than the length of the second conductive trace 81. In the second display area S2/S3, the length of the first conductive trace 82 gradually increases in the direction away from the third display area S7.

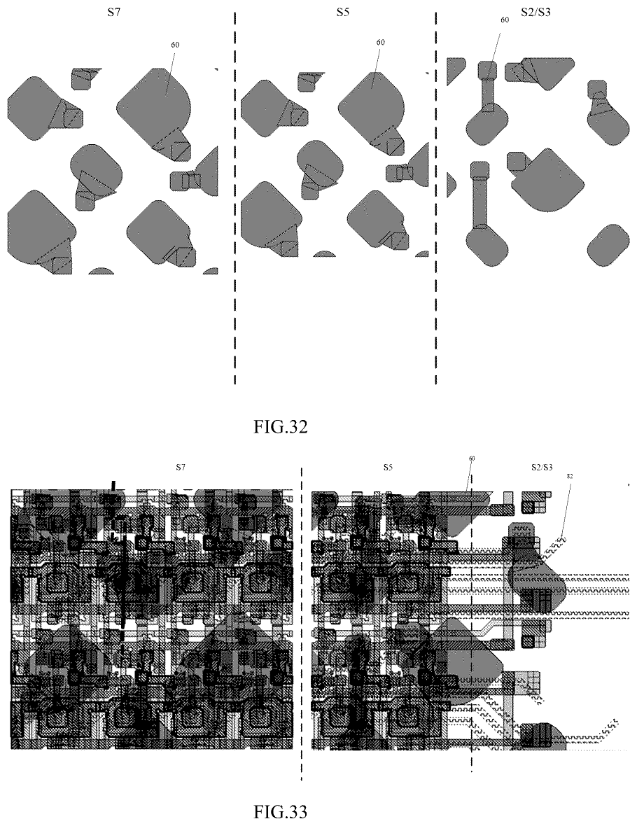

As shown in FIG. 32 and FIG. 33, in the third display area S7, the transitional display area S5, and the second display area S2/S3, the anode layer is used to form the anode 60 of the light emitting element.

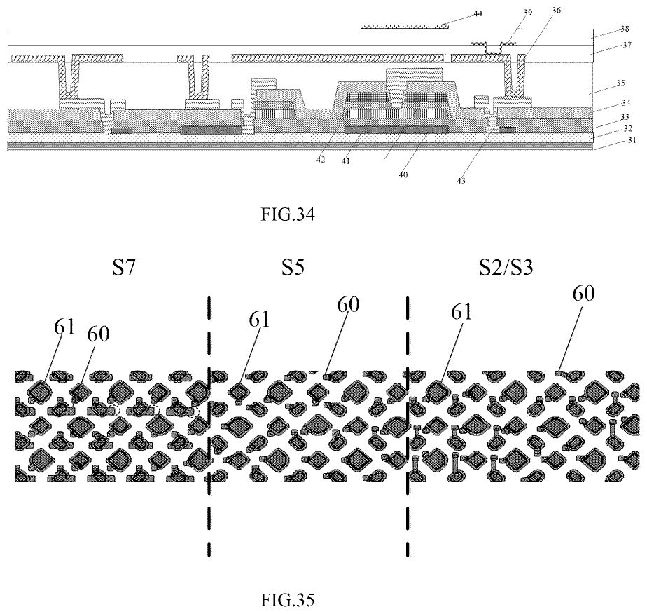

FIG. 34 is a schematic cross-sectional view in the direction of the black dotted line in FIG. 33. As shown in FIG. 34, the display substrate includes a substrate 31, a flexible substrate 32, a semiconductor layer 40, a gate insulating layer 33, a first gate metal layer 41, a second gate metal layer 42, an interlayer insulating layer 34, a first source-drain metal layer 43, a first planar layer 35, a second source-drain metal layer 36, a second planar layer 37, an ITO layer 39, a third planar layer 38, and a cathode layer 44. The substrate 31 and the flexible substrate 32 constitute a base.

FIG. 35 is a schematic diagram of the stacking of the pixel defining layer and the anode layer, where 61 is the opening of the pixel defining layer. It can be seen that the size of the opening 61 of the pixel defining layer of the third display area S7 can be the same as the size of the opening 61 of the second display area S2/S3, and the area of the anode 60 of the third display area S7 is larger than the area of the anode 60 of the second display area S2/S3. Specifically, an irregular portion as shown in the dotted box can be added to the anode 60 of the third display area S7 to make the area of the anode 60 of the third display area S7 larger than the area of the anode 60 of the second display area S2/S3.

An embodiment of the present disclosure further provides a display device, including the display substrate provided by the above embodiment.

It should be noted that the display device can be any product or component with a display function, such as a television, a monitor, a digital photo frame, a mobile phone, a tablet computer, etc., where the display device also includes a flexible circuit board, a printed circuit board and a backplane, etc.

As shown in FIG. 28, the anode of the light-emitting element in the first display area is connected to the sub-pixel driving circuit via the second conductive trace 81. Since the sub-pixel driving circuit is provided in the first display area, the distance between the anode of the light-emitting element and the sub-pixel driving circuit is relatively short. Therefore, the length of the second conductive trace 81 is shorter than the length of the first conductive trace 82. When the line width of the second conductive trace 81 is substantially the same as the line width of the first conductive trace 82, the area of the second conductive trace 81 is smaller than the area of the first conductive trace 82. In the first display area, the second conductive trace 81 and the anode 60 as a whole serve as a plate of the N4 point capacitor; in the second display area, the first conductive trace 82 and the anode 60 as a whole serve as a plate of the N4 point capacitor; since the area of the second conductive trace 81 is smaller than the area of the first conductive trace 82, when the area of the anode in the first display area and the anode in the second display area are the same, the area of one plate of the N4 point capacitor corresponding to the first display area will be smaller than the area of one plate of the N4 point capacitor corresponding to the second display area, resulting in the N4 point capacitor corresponding to the first display area being smaller than the N4 point capacitor corresponding to the second display area, and a difference occurs between the N4 point capacitors corresponding to the first display area and the second display area, so that the second display area cannot light up or cannot reach the same brightness as the first display area; in this embodiment, by reducing the area of at least part of the anode in the second display area, the purpose of reducing the difference in the N4 point capacitors corresponding to the first display area and the second display area is achieved, so that the brightness of the second display area is close to that of the first display area, thereby ensuring the display effect of the display substrate.

The display substrate provided by the embodiment of the present disclosure also has the above-mentioned beneficial effects when including the above-mentioned display substrate, which will not be described in detail here.

It should be noted that the signal line extends along the X direction means that the signal line includes a main part and a secondary part connected to the main part, the main part is a line, a line segment or a strip-shaped body, the main part extends along the X direction, and the length of the main part extending along the X direction is greater than the length of the secondary part extending along other directions.

It should be noted that the “same layer” in the embodiment of the present disclosure may refer to a film layer on the same structural layer. Or, for example, a film layer on the same layer may be a film layer for forming a specific pattern formed by the same film forming process, and then the film layer is patterned by the same mask through a single composition process to form a layer structure. Depending on the specific pattern, a single composition process may include multiple exposure, development or etching processes, and the specific pattern in the formed layer structure may be continuous or discontinuous. These specific patterns may also be at different heights or have different thicknesses.

In the various method embodiments of the present disclosure, the serial numbers of the steps cannot be used to limit the sequence of the steps. For ordinary technicians in this field, without paying any creative work, changes to the sequence of the steps are also within the protection scope of the present disclosure.

It should be noted that each embodiment in this specification is described in a progressive manner, and the same or similar parts between the embodiments can be referred to each other, and each embodiment focuses on the differences from other embodiments. In particular, for the method embodiment, since it is basically similar to the product embodiment, the description is relatively simple, and the relevant parts can be referred to the partial description of the product embodiment.

Unless otherwise defined, the technical terms or scientific terms used in the present disclosure should be understood by people with ordinary skills in the field to which the present disclosure belongs. The “first”, “second” and similar words used in the present disclosure do not indicate any order, quantity or importance, but are only used to distinguish different components. “Include” or “include” and similar words mean that the elements or objects appearing before the word cover the elements or objects listed after the word and their equivalents, without excluding other elements or objects. “Connect”, “couple” or “connected” and similar words are not limited to physical or mechanical connections, but can include electrical connections, whether direct or indirect. “Up”, “down”, “left”, “right” and the like are only used to indicate relative positional relationships. When the absolute position of the described object changes, the relative positional relationship may also change accordingly.

It will be understood that when an element such as a layer, film, region, or substrate is referred to as being “on” or “under” another element, it can be “directly on” or “under” the other element or intervening elements may be present.

In the description of the above embodiments, specific features, structures, materials or characteristics may be combined in a suitable manner in any one or more embodiments or examples.

The above is only a specific embodiment of the present disclosure, but the protection scope of the present disclosure is not limited thereto. Any person skilled in the art who is familiar with the technical field can easily think of changes or substitutions within the technical scope disclosed in the present disclosure, which should be included in the protection scope of the present disclosure. Therefore, the protection scope of the present disclosure should be based on the protection scope of the claims.

1. A display substrate, comprising: a substrate and a plurality of sub-pixels arranged on the substrate, the sub-pixels comprising a sub-pixel driving circuit and a light-emitting element, the display substrate comprising a first display area and a second display area located around the first display area, wherein the first display area is provided with the sub-pixel driving circuit and the light-emitting element, the second display area is provided with the light-emitting element, the second display area is not provided with the sub-pixel driving circuit, an anode of the light-emitting element in the second display area is connected to the sub-pixel driving circuit arranged in the first display area through a first conductive trace, and the anode of the light-emitting element in the first display area is connected to the sub-pixel driving circuit arranged in the first display area through a second conductive trace; wherein
an area of at least part of the anode of the second display area is smaller than an area of the anode of the sub-pixel of the same color in the first display area.

2. The display substrate according to claim 1, wherein
a first display area comprises a third display area and a transitional display area, and the transitional display area is located between the third display area and the second display area;
an area of at least part of the anode in the transitional display area is smaller than that of the anode of the same color sub-pixel in the third display area, and the area of at least part of the anode in the transitional display area is larger than the area of the anode of the same color sub-pixel in the second display area.

3. The display substrate according to claim 2, wherein the sub-pixels comprise a green sub-pixel, a red sub-pixel and a blue sub-pixel,
the area of the first anode of the transitional display area is smaller than the area of the first anode of the sub-pixel of the same color in the third display area; the area of the first anode of the transitional display area is larger than the area of the first anode of the sub-pixel of the same color in the second display area;
wherein the first anode is the anode of the green sub-pixel, the red sub-pixel and the blue sub-pixel; or
the first anode is the anode of the green sub-pixel.

4. The display substrate according to claim 3, wherein
in the transitional display area and the second display area, the area of the first anode of the sub-pixel of the same color gradually decreases in a direction away from the third display area.

5. The display substrate according to claim 4, wherein
in the transitional display area and the second display area, a plurality of pixel repetition units are sequentially arranged in a direction away from the third display area, the pixel repetition unit comprises at least one sub-pixel, and in each of the pixel repetition units, the areas of the first anodes of sub-pixels of the same color are equal; the areas of the first anodes of sub-pixels of the same color in different pixel repetition units gradually decrease.

6. The display substrate according to claim 1, wherein the sub-pixels comprise a green sub-pixel, a red sub-pixel and a blue sub-pixel,
the area of the first anode of the first display area is larger than the area of the first anode of the sub-pixel of the same color in the second display area;
wherein the first anode is the anode of the green sub-pixel, the red sub-pixel and the blue sub-pixel; or
the first anode is the anode of the green sub-pixel.

7. The display substrate according to claim 6, wherein in the second display area, the area of the first anode of the sub-pixel of the same color gradually decreases along a direction away from the first display area.

8. The display substrate according to claim 7, wherein
in the second display area, the plurality of pixel repetition units are arranged in sequence along a direction away from the first display area, the pixel repetition units comprise at least one sub-pixel, and in each of the pixel repetition units, the areas of the first anodes of sub-pixels of the same color are equal; the areas of the first anodes of sub-pixels of the same color in different pixel repetition units gradually decrease.

9. The display substrate according to claim 5, wherein the area of the first anode of the (k+1)-th pixel repeating unit is n times the area of the first anode of the same color sub-pixel of the k-th pixel repeating unit, k is a positive integer, and n is less than 1 and greater than 0.

10. The display substrate according to claim 1, wherein a line width of the second conductive trace is greater than a line width of the first conductive trace.

11. The display substrate according to claim 1, wherein the first conductive trace is transparent, and the second conductive trace is transparent.

12. The display substrate according to claim 1, wherein
conductive trace connected to the light-emitting element of the sub-pixel with the first luminous color on the substrate is equal to the orthographic projection area of the second conductive trace connected to the light-emitting element of the sub-pixel with the same luminous color on the substrate.

13. The display substrate according to claim 1, wherein a difference between a sum of the areas of the orthographic projections of the anode of the sub-pixel having the first luminous color and the corresponding first conductive trace on the substrate and a sum of the areas of the orthographic projections of the anode of the sub-pixel having the same luminous color and the corresponding second conductive trace on the substrate is within 10%.

14. The display substrate according to claim 1, wherein the second display area is provided with a gate driving circuit or a light emitting control circuit.

15. The display substrate according to claim 1, wherein the display substrate comprises a plurality of power lines, a plurality of light emitting control lines, a plurality of gate lines, a plurality of data lines, a plurality of reset lines, and a plurality of initialization signal lines;
the sub-pixel driving circuit comprises: a storage capacitor, a first reset transistor, a data writing transistor, a power control transistor, a light emitting control transistor, a second reset transistor, a driving transistor and a compensation transistor;
the compensation transistor comprises an active layer and a gate, the active layer of the compensation transistor comprises a first electrode, a second electrode, and a channel portion connecting the first electrode and the second electrode, the driving transistor comprises an active layer and a gate, the active layer of the driving transistor comprises a first electrode, a second electrode, and a channel portion connecting the first electrode and the second electrode;
a first electrode of the compensation transistor is coupled to the second electrode of the driving transistor, and the second electrode of the compensation transistor is coupled to the gate of the driving transistor; the driving transistor is used to drive the light-emitting element to emit light, and the first electrode of the driving transistor is connected to the anode;
a gate electrode of the first reset transistor is coupled to the corresponding reset line, the first electrode of the first reset transistor is coupled to the corresponding initialization signal line, and the second electrode of the first reset transistor is coupled to the gate of the driving transistor;
a gate electrode of the data writing transistor is coupled to the corresponding gate line, the first electrode of the data writing transistor is coupled to the corresponding data line, and the second electrode of the data writing transistor is coupled to the first electrode of the driving transistor;
a gate electrode of the power control transistor is coupled to the corresponding light emitting control line, the first electrode of the power control transistor is coupled to the corresponding power line, and the second electrode of the power control transistor is coupled to the first electrode of the driving transistor;
a gate of the light emitting control transistor is coupled to the corresponding light emitting control line, the first electrode of the light emitting control transistor is coupled to the second electrode of the driving transistor, and the second electrode of the light emitting control transistor is coupled to the corresponding light emitting element;
a gate electrode of the second reset transistor is coupled to the corresponding reset line, the first electrode of the second reset transistor is coupled to the corresponding initialization signal line, and the second electrode of the second reset transistor is coupled to the corresponding light emitting element;
a first plate of the storage capacitor is coupled to the gate of the driving transistor, and a second plate of the storage capacitor is coupled to the corresponding power line.

16. The display substrate according to claim 15, wherein the second display area is provided with a data fan-out line connected to the data line, and an orthographic projection of the data fan-out line on the substrate does not overlap with an orthographic projection of the anode on the substrate.

17. The display substrate according to claim 15, wherein the display substrate comprises a first metal layer and a second metal layer located on a side of the first metal layer away from the substrate, the first metal layer comprises the initialization signal line and a node connection line, the node connection line connects the gate of the driving transistor and the drain of the compensation transistor, the second metal layer comprises a shielding pattern, the shielding pattern is connected to the initialization signal line through a via, and an orthographic projection of the initialization signal line on the substrate at least partially overlaps with an orthographic projection of the node connection line on the substrate.

18. The display substrate according to claim 17, wherein the first metal layer also comprises a first adapter block and a second adapter block, the second metal layer also comprises a third adapter block, the drain of the light-emitting control transistor is connected to the first adapter block, the drain of the second reset transistor is connected to the second adapter block, the first adapter block and the second adapter block are connected through the third adapter block, and the third adapter block is connected to the anode.

19. A display device, comprising a display substrate according to claim 1.
